(19) United States
(12) Patent Application Publication
(10) Pub. No.: US 2026/0282621 A1
(43) Pub. Date: Sep. 17, 2026

(54) LIGHT-EMITTING SUBSTRATE AND METHOD FOR MANUFACTURING SAME, AND DISPLAY DEVICE

(71) Applicants: BOE MLED Technology Co., Ltd., Beijing (CN); BOE Technology Group Co., Ltd., Beijing (CN)

(72) Inventors: Jian LI, Beijing (CN); Zhifu YANG, Beijing (CN); Fuqun ZHANG, Beijing (CN); Teng ZHANG, Beijing (CN); Jiajia SHEN, Beijing (CN); Shubai ZHANG, Beijing (CN); Huaiyong ZHANG, Beijing (CN); Shiwei LI, Beijing (CN); Hao CHENG, Beijing (CN); Wei ZHANG, Beijing (CN); Longtao HUANG, Beijing (CN); Chunbo WU, Beijing (CN)

(21) Appl. No.: 19/469,738

(22) PCT Filed: Apr. 16, 2024
(86) PCT No.: PCT/CN2024/088099

§ 371 Date: Sep. 26, 2025

(30) Foreign Application Priority Data
May 19, 2023 (CN) 202310574279.3

(51) Int. Cl. H10H 20/857; H10H 20/01; H10H 20/854; H10H 29/14

(52) U.S. Cl. CPC H10H 20/857; H10H 20/0364; H10H 20/854; H10H 29/14

(57) ABSTRACT

A light-emitting substrate includes: a wiring substrate including a base substrate, a wiring layer, and a first insulating protection layer, here the wiring layer including a plurality of first pad groups, the first insulating protection layer including a plurality of first openings, and an orthographic projection of the first pad group on the base substrate is within an orthographic projection of the first opening on the base substrate; a plurality of light-emitting devices at a side of the first pad groups facing away from the base substrate, here each of the light-emitting devices is bound to a corresponding one of the first pad groups; and a plurality of protection structures at a side of the light-emitting device facing away from the base substrate. Each of the protection structures includes a first part and a second part at a side of the first part facing away from the base substrate.

### CROSS REFERENCE TO RELATED APPLICATIONS

The application is a national phase entry under 35 U.S.C § 371 of International Application No. PCT/CN2024/088099, filed Apr. 16, 2024, which claims the priority to Chinese Patent Application No. 202310574279.3, filed to the China National Intellectual Property Administration on May 19, 2023 and entitled “LIGHT-EMITTING SUBSTRATE AND METHOD FOR MANUFACTURING SAME, AND DISPLAY DEVICE”, which is incorporated in its entirety herein by reference.

### TECHNICAL FIELD

The disclosure herein relates to the field of display technology, and particularly relates to a light-emitting substrate, a method for manufacturing the light-emitting substrate, and a display device.

### BACKGROUND

Micro light-emitting diodes are increasingly being used in the display field due to their smaller size, ultra-high brightness, and long lifespan.

### SUMMARY

Embodiments of the discourse provide a light-emitting substrate, a method for manufacturing the light-emitting substrate and a display device, for improving the yield of light-emitting substrates.

The embodiments of provide a light-emitting substrate, and the light-emitting substrate includes: a wiring substrate, a plurality of light-emitting devices and a plurality of protective structures. The wiring substrate includes a base substrate; a wiring layer, located at a side of the base substrate; and a first insulating protective layer, located at a side of the wiring layer facing away from the base substrate. The wiring layer includes a plurality of first pad groups, the first insulating protective layer includes a plurality of first openings, and an orthographic projection of the first pad group on the base substrate is within an orthographic projection of the first opening on the base substrate. The plurality of light-emitting devices is located at a side of the plurality of first pad groups facing away from the base substrate. Each of the plurality of light-emitting devices is bound to a corresponding one of the plurality of first pad groups. The plurality of protective structures is located at a side of the plurality of light-emitting devices facing away from the base substrate. Each of the plurality of protective structures includes: a first portion, and a second portion located at a side of the first portion facing away from the base substrate; and an orthographic projection of the first portion on the base substrate at least covers an orthographic projection of an area between the light-emitting device and the first insulating protective layer on the base substrate.

In some embodiments, the first portion is provided with a first transmittance for visible light, the second portion is provided with a second transmittance for the visible light, and an absolute value of a difference between the first transmittance and the second transmittance is less than or equal to 5%, and the first transmittance is greater than or equal to 90%, and the second transmittance is greater than or equal to 90%.

In some embodiments, the first portion is provided with a first refractive index for visible light, the second portion is provided with a second refractive index for the visible light, and an absolute value of a difference between the first refractive index and the second refractive index is less than or equal to 0.2.

In some embodiments, a material of the first portion includes a first adhesive material, and a material of the second portion includes a second adhesive material. Viscosity of the first adhesive material is less than viscosity of the second adhesive material.

In some embodiments, the viscosity of the first light-transmitting adhesive material is greater than or equal to 3000 Pas and less than 6000 Pa·s. The viscosity of the second adhesive material is greater than or equal to 6000 Pa·s and less than or equal to 9000 Pa·s.

In some embodiments, a volume of the first portion is smaller than a volume of the second portion.

In some embodiments, a maximum distance h1 from a surface of the light-emitting device facing away from the base substrate to the base substrate, a maximum distance h2 from a surface of the first portion facing away from the base substrate to the base substrate, and a maximum distance h3 from a surface of the second portion facing away from the base substrate to the base substrate satisfy: 0.53≤h2/h1≤1.33, 3.33≤h3/h1≤5.

In some embodiments, the maximum distance h2 from the surface of the first portion facing away from the base substrate to the base substrate is greater than a maximum distance h4 from a surface of the first insulating protective layer facing away from the base substrate to the base substrate.

In some embodiments, 0.13≤h4/h1≤0.4.

In some embodiments, 100 μm≤h1≤200 μm, 20 μm≤h4≤60 μm, 80 μm≤h2≤200 μm, and 500 μm≤h3≤750 μm.

In some embodiments, the orthographic projection of the first portion on the base substrate is within an orthographic projection of the second portion on the base substrate.

In some embodiments, the plurality of light-emitting devices are arranged in an array along a first direction and a second direction, and the first direction intersects the second direction. In the first direction or in the second direction, the orthographic projection of the first opening on the base substrate is provided with a first size L1, an orthographic projection of the light-emitting device on the base substrate is provided with a second size L2, the orthographic projection of the first portion on the base substrate is provided with a third size L3, and the orthographic projection of the second portion on the base substrate is provided with a fourth size L4, and the first size L1, the second size L2, the third size L3 and the fourth size L4 satisfy following relationship: L1> L2, L3>L1, L4>L3.

In some embodiments, in the first direction or in the second direction, the first size L1, the second size L2, and the third size L3 satisfy:

$$L 2 + 150 μm \geq L 1 \geq L 2 + 50 μm ;$$

$$L 3 \geq \sqrt{2} \cdot L 2 + 50 μm .$$

In some embodiments, 700 μm>L2>100 μm; and the fourth size L4 satisfies: 1300 μm≥L4≥1000 μm.

In some embodiments, a surface of the side of the first portion facing away from the base substrate and a surface of a side of the second portion facing away from the base substrate are curved surfaces.

The embodiments of the disclosure provide a method for manufacturing a light-emitting substrate, including: manufacturing a wiring substrate; here the wiring substrate includes: a base substrate, a wiring layer located at a side of the base substrate, and a first insulating protective layer located at a side of the wiring layer facing away from the base substrate; the wiring layer includes a plurality of first pad groups, the first insulating protective layer includes a plurality of first openings, and an orthographic projection of the first pad group on the base substrate is within an orthographic projection of the first opening on the base substrate; bonding each of a plurality of light-emitting devices to a corresponding one of the plurality of first pad groups; forming a first portion at a side of the light-emitting device facing away from the base substrate; here, an orthographic projection of the first portion on the base substrate at least covers an orthographic projection of an area between the light-emitting device and the first insulating protective layer on the base substrate; forming a second portion at a side of the first portion facing away from the base substrate; herein in a direction perpendicular to the base substrate, a maximum thickness of the first portion is smaller than a maximum thickness of the second portion.

In some embodiments, the forming the first portion at the side of the light-emitting device facing away from the base substrate includes: printing a first adhesive material at the side of the light-emitting device facing away from the base substrate and curing the first adhesive material to form the first portion. The forming the second portion at the side of the first portion facing away from the base substrate includes: printing a second adhesive material at the side of the first portion facing away from the base substrate and curing the second adhesive material to form the second portion. A volume of the first portion is smaller than a volume of the second portion.

The embodiments of the disclosure provide a display device, including the light-emitting substrate provided by the embodiments of the disclosure.

### BRIEF DESCRIPTION OF FIGURES

In order to illustrate technical solutions of embodiments of the disclosure more clearly, drawings needing to be used in descriptions of the embodiments will be introduced below briefly. Apparently, the drawings described below are only some embodiments of the disclosure, and those ordinarily skilled in the art can further obtain other drawings according to these drawings without inventive efforts.

FIG. 1 is a schematic structural diagram of a light-emitting substrate provided by the related art.

FIG. 2 is a schematic structural diagram of a light-emitting substrate provided by an embodiment of the disclosure.

FIG. 3 is a top view of a light-emitting substrate provided by an embodiment of the disclosure.

FIG. 4 is a schematic flow chart of a method for manufacturing a light-emitting substrate provided by an embodiment of the disclosure.

FIG. 5 is schematic flow chart of another method for manufacturing a light-emitting substrate provided by an embodiment of the disclosure.

FIG. 6 is a schematic flow chart of yet another method for manufacturing a light-emitting substrate provided by an embodiment of the disclosure.

FIG. 7 is a schematic structural diagram of a display device provided by an embodiment of the disclosure.

### DETAILED DESCRIPTION

In order to make the objectives, technical solutions and advantages of the embodiments of the disclosure clearer, the technical solutions of the embodiments of the disclosure are described clearly and completely below with reference to the drawings of the embodiments of the disclosure. Apparently, the described embodiments are some, not all, of the embodiments of the disclosure. In addition, the embodiments and the features in the embodiments of the disclosure can be combined with each other without conflict. Based on the described embodiments of the disclosure, all other embodiments obtained by those of ordinary skill in the art without inventive efforts fall within the protection scope of the disclosure.

Unless otherwise indicated, the technical or scientific terms used in the disclosure shall have the usual meanings understood by a person of ordinary skill in the art to which the disclosure belongs. The words “first”, “second” and the like used in the disclosure do not indicate any order, quantity or importance, but are only used to distinguish different components. The word “including” or “containing” and the like, means that an element or item preceding the word covers an element or item listed after the word and the equivalent thereof, without excluding other elements or items. The word “connection” or “coupling” and the like is not restricted to physical or mechanical connection, but may include electrical connection, whether direct or indirect.

It should be noted that the sizes and shapes of the figures in the drawings do not reflect true proportions and are only intended to illustrate the disclosure. And the same or similar reference numbers throughout represent the same or similar elements or elements with the same or similar functions.

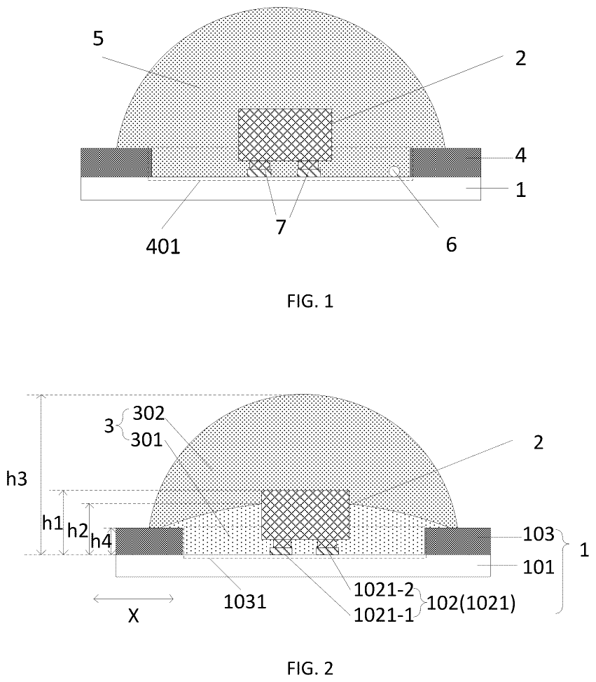

In the related art, as shown in FIG. 1, a light-emitting substrate includes a wiring substrate 1, and a reflection layer 4 located above the wiring substrate 1. The reflection layer 4 has an opening 401, the opening 401 exposes a pad 7 on the wiring substrate that is bound and connected to the light-emitting device 2, and exposes a protective structure 5 for protecting the light-emitting device 2. In the process of forming a protective structure by a printing process, a transparent slurry in a solid-liquid mixed state falls on the corresponding area and is cured to form a protective structure. In order to ensure that the protective structure finally formed has a specific morphology, the transparent slurry used needs to have a large viscosity. The inventor found that due to a small size of the opening 401, a distance from the light-emitting device to an edge of the opening 401 is small, which easily leads to a situation where the air below the opening 401 corresponding to the falling position of the transparent slurry cannot be discharged smoothly, as shown in FIG. 1, resulting in the presence of bubbles 6 in the finally formed protective structure. The presence of bubbles 6 causes the uniformity of the brightness of the light emitted from the protective structure by the light-emitting device 2 to deteriorate, thereby affecting the overall brightness uniformity of the light-emitting substrate.

Embodiments of the disclosure provide a light-emitting substrate, as shown in FIG. 2, the light-emitting substrate includes a wiring substrate 1, a plurality of light-emitting device 2, and a plurality of protective structure 3.

The wiring substrate 1 includes: a base substrate 101, a wiring layer 102 located at a side of the base substrate 101, and a first insulating protective layer 103 located at a side of the wiring layer 102 facing away from the base substrate 101. The wiring layer 102 includes a plurality of first pad groups 1021. The first insulating protective layer 103 includes a plurality of first openings 1031, and an orthographic projection of the first pad group 1021 on the base substrate 101 is within an orthographic projection of the first opening 1031 on the base substrate 101.

The plurality of light-emitting devices 2 are located at a side of the plurality of first pad groups 1021 facing away from the base substrate 101. Each of the plurality of light-emitting devices 2 is bound to a corresponding one of the plurality of first pad groups 1021.

The plurality of protective structures 3 are located at a side of the plurality of light-emitting device 2 facing away from the base substrate 101; each of the plurality of protective structures 3 includes: a first portion 301, and a second portion 302 located at a side of the first portion 301 facing away from the base substrate 101; an orthographic projection of the first portion 301 on the base substrate 101 at least covers an orthographic projection of an area between the light-emitting device 2 and the first insulating protective layer 103 on the base substrate 101.

In the light-emitting substrate provided in the embodiments of the disclosure, the protective structure includes a first portion and a second portion, and the second portion is located at the side of the first portion facing away from the base substrate, that is, in the embodiments of the disclosure, the protective structure is fabricated in two steps: first, the first portion that at least covers the area between the light-emitting device and the first insulating protective layer is formed, and then the second portion is formed. In this way, compared with forming the protective structure once, it is more conducive to exhausting the air between the protective structure and the wiring substrate at the first opening, avoiding the formation of bubbles between the protective structure and the wiring substrate, thereby avoiding abnormal brightness of the light emitted from the protective structure, improving the yield of the light-emitting substrate, and improving the brightness uniformity of the light-emitting substrate.

In some embodiments, the number of the light-emitting devices is equal to the number of the protective structures.

In a specific implementation, each light-emitting device is covered by a protective structure. The protective structure can be used to prevent the light-emitting device from being damaged.

In some embodiments, as shown in FIG. 2, a surface of a side of the second portion 302 facing away from the base substrate 101 is a curved surface. That is, a surface of the protective structure 3 facing away from the base substrate 101 is a curved surface. The protective structure 3 of this shape as shown in FIG. 2 can modulate the light emitted by the light-emitting device and improve the brightness and efficiency of the light emitted from the front viewing angle.

In some embodiments, as shown in FIG. 2, a surface of the side of the first portion 301 facing away from the base substrate 101 may also be a curved surface.

In some embodiments, both the first portion and the second portion include an adhesive material.

In some embodiments, the first portion and the second portion include the same adhesive material.

Alternatively, in some embodiments, the first portion and the second portion include different adhesive materials.

In some embodiments, a material of the first portion includes a first adhesive material, and a material of the second portion includes a second adhesive material; the viscosity of the first adhesive material is less than the viscosity of the second adhesive material.

In the light-emitting substrate provided by the embodiments of the disclosure, in the protective structure, the first adhesive material included in the first portion covering the area between the light-emitting device and the first insulating protective layer has a lower viscosity, which is more conducive to air discharge, and can further avoid the formation of bubbles between the protective structure and the wiring substrate, thereby avoiding abnormal brightness of light emitted from the protective structure, and is more conducive to improving the yield of the light-emitting substrate and improving the brightness uniformity of the light-emitting substrate.

In some embodiments, the viscosity of the second adhesive material is greater than or equal to 6000 Pa·s and less than or equal to 9000 Pa·s.

The viscosity of the first adhesive material is greater than or equal to 3000 Pas and less than 6000 Pa·s.

In a specific implementation, an aspect ratio of the protective structure 3 is related to the thixotropy of the adhesive material. The protective structure 3 formed by materials with different viscosities has different aspect ratios. The first adhesive material and the second adhesive material with corresponding viscosities can be selected according to the required aspect ratio of the protective structure 3.

In some embodiments, the adhesive materials included in the first portion and the second portion are both light-transmitting adhesive materials.

In some embodiments, the first portion is provided with a first transmittance to visible light, the second portion is provided with a second transmittance to visible light, the first transmittance is greater than or equal to 90%, and the second transmittance is greater than or equal to 90%. This ensures that the first portion and the second portion have a high transmittance to the visible light, improves the brightness of the light emitted from the protective structure, and is conducive to improving the light utilization rate of the light-emitting substrate.

In a specific implementation, the first transmittance may be equal to the second transmittance. Of course, the first transmittance may be unequal to the second transmittance.

In some embodiments, an absolute value of a difference between the first transmittance and the second transmittance is less than or equal to 5%.

In the light-emitting substrate provided by the embodiments of the disclosure, the absolute value of the difference between the first transmittance and the second transmittance is less than or equal to 5%, that is, the difference in transmittance between the first portion and the second portion is small, so that light can pass through the protective structure smoothly and avoid affecting the overall transmittance of the protective structure.

In some embodiments, to reduce the probability of total reflection of the emitted light of the light-emitting device at the interface between the protective structure and the air, a refractive index of the protective structure may be between a refractive index of the light-emitting device and a refractive index of the air.

In some embodiments, the first portion is provided with a first refractive index for visible light and the second portion is provided with a second refractive index for visible light.

In some embodiments, the first refractive index is equal to the second refractive index, which avoids the need to adjust different parameters when manufacturing the first portion and the second portion, thereby saving costs.

Alternatively, in some embodiments, the first refractive index is not equal to the second refractive index.

In some embodiments, an absolute value of the difference between the first refractive index and the second refractive index is less than or equal to 0.2.

In the light-emitting substrate provided by the embodiments of the disclosure, the absolute value of the difference between the first refractive index and the second refractive index is less than or equal to 0.2, that is, the difference in refractive index between the first portion and the second portion is small, thereby preventing light from being deflected at a large angle at the interface between the first portion and the second portion.

In some embodiments, as shown in FIG. 2, a volume of the first portion 301 is smaller than a volume of the second portion 302.

That is, in the light-emitting substrate provided in the embodiments of the disclosure, the volume of the first portion is less than half of the volume of the entire protective structure. The smaller volume of the first portion is more conducive to discharging the air between the protective structure and the wiring substrate at the first opening, avoiding the existence of bubbles between the protective structure and the wiring substrate, thereby avoiding abnormal brightness of light emitted from the protective structure, improving the yield of the light-emitting substrate, and improving the brightness uniformity of the light-emitting substrate.

In some embodiments, as shown in FIG. 2, a maximum distance h1 from a surface of the light-emitting device 2 facing away from the base substrate 101 to the base substrate 101, a maximum distance h2 from a surface of the first portion 301 facing away from the base substrate 101 to the base substrate 101, and a maximum distance h3 from a surface of the second portion 302 facing away from the base substrate 101 to the base substrate 101 satisfy:

$$0.53 \leq h 2 / h 1 \leq 1.33 , 3.33 \leq h 3 / h 1 \leq 5.$$

It should be noted that h1> h2 is used as an example in FIG. 2 for illustration. In a specific implementation, h2>h1 may also be set, that is, the first portion also covers the light-emitting device. Alternatively, h1=h2 may also be set.

In some embodiments, as shown in FIG. 2, the maximum distance h2 from the surface of the first portion 301 facing away from the base substrate 101 to the base substrate 101 is greater than the maximum distance h4 from the surface of the first insulating protective layer 103 facing away from the base substrate 101 to the base substrate 101. That is, the maximum thickness of the first portion is greater than the maximum thickness of the first insulating protective layer, which is more conducive to achieving that the first portion covers the area between the light-emitting device and the first insulating protective layer at the first opening.

In some embodiments, 0.13≤h4/h1≤0.4.

In some embodiments, 100 μm≤h1≤200 μm, 20 μm≤h4≤60 μm, 80 μm≤h2≤200 μm, and 500 μm≤h3≤750 μm.

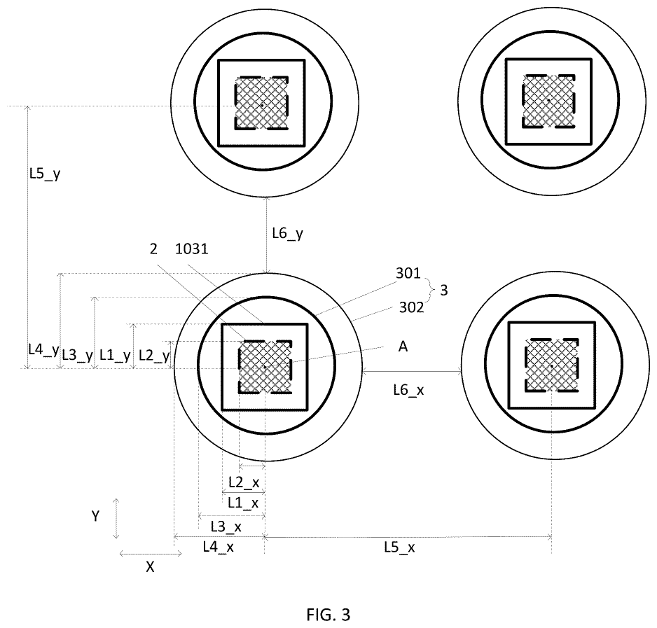

In some embodiments, as shown in FIG. 2 and FIG. 3, the orthographic projection of the first portion 301 on the base substrate 101 is within an orthographic projection of the second portion 302 on the base substrate 101.

That is, the second portion completely covers the first portion, which can improve the protective effect of the protective structure on the light-emitting device. The morphology of the surface of the second portion facing away from the base substrate is the morphology of the protective structure.

In some embodiments, as shown in FIG. 3, the orthographic projection of the first portion 301 on the base substrate 101 and the orthographic projection of the second portion 302 on the base substrate 101 are circular in shape.

In some embodiments, as shown in FIG. 3, the orthographic projection of the light-emitting device 2 on the base substrate 101 and the orthographic projection of the first opening 1031 on the base substrate 101 are rectangular in shape. FIG. 3 takes the orthographic projection of the light-emitting device 2 on the base substrate 101 and the orthographic projection of the first opening 1031 on the base substrate 101 as a square as an example for illustration.

In some embodiments, as shown in FIG. 3, a center of a pattern of the orthographic projection of the first portion 301 on the base substrate 101, a center of a pattern of the orthographic projection of the second portion 302 on the base substrate 101, a center of the orthographic projection of the light-emitting device 2 on the base substrate 101, and a center of the orthographic projection of the first opening 1031 on the base substrate 101 coincide with each other. In FIG. 3, the center of the pattern of the orthographic projection of the first portion 301 on the base substrate 101, the center of the pattern of the orthographic projection of the second portion 302 on the base substrate 101, the center of the orthographic projection of the light-emitting device 2 on the base substrate 101, and the center of the orthographic projection of the first opening 1031 on the base substrate 101 coincide with point A in the figure.

In some embodiments, as shown in FIG. 3, a plurality of light-emitting devices 2 are arranged in an array along a first direction X and a second direction Y, and the first direction X intersects the second direction Y. FIG. 3 takes an example that the first direction X is perpendicular to the second direction Y for illustration.

In some embodiments, as shown in FIG. 3, in the first direction X or in the second direction Y, the orthographic projection of the first opening 1031 on the base substrate is provided with a first size L1, the orthographic projection of the light-emitting device 2 on the base substrate is provided with a second size L2, the orthographic projection of the first portion 301 on the base substrate is provided with a third size L3, and the orthographic projection of the second portion 302 on the base substrate is provided with a fourth size L4. The first size L1, the second size L2, the third size L3 and the fourth size L4 satisfy the following relationship:

$$L 1 > L 2 , L 3 > L 1 , L 4 > L 3 .$$

It should be noted that if the shape of the orthographic projection of the first opening or the light-emitting device or the first portion or the second portion on the base substrate is a rectangle and its sides are parallel to the first direction or the second direction, then the corresponding first size L1 or the second size L2 or the third size L3 or the fourth size L4 is half of the side length of the above-mentioned rectangle. If the shape of the orthographic projection of the first opening or the light-emitting device or the first portion or the second portion on the base substrate is a polygon, then the corresponding first size L1 or the second size L2 or the third size L3 or the fourth size L4 is half of the diagonal of the above-mentioned polygon. If the shape of the orthographic projection of the first opening or the light-emitting device or the first portion or the second portion on the base substrate is a circle, then the first size L1 or the second size L2 or the third size L3 or the fourth size L4 is the radius of the above-mentioned circle. If the shape of the orthographic projection of the first opening or the light-emitting device or the first portion or the second portion on the base substrate is an ellipse, then the first size L1 or the second size L2 or the third size L3 or the fourth size L4 is half of the major axis or minor axis of the above-mentioned ellipse.

In the light-emitting substrate provided in the embodiments of the disclosure, the third size L3 is larger than the first size L1, and the fourth size L4 is larger than the first size L1, that is, the first portion not only covers the area between the light-emitting device and the first insulating protective layer at the first opening, but also covers a partial area of the first insulating protective layer close to the first opening, and the second portion also covers a partial area of the first insulating protective layer close to the first opening, which is beneficial to improving the protective effect of the light-emitting device and avoiding damage to the light-emitting device.

It should be noted that in FIG. 3, the orthographic projections of the first opening and the light-emitting device on the base substrate are both rectangular and sides of the rectangle are parallel to the first direction or the second direction, and the orthographic projections of the first portion and the second portion on the base substrate are both circular, that is, the first size L1_x in the first direction X is equal to the first size L1_y in the second direction Y, the second size L2_x in the first direction X is equal to the second size L2_y in the second direction Y, the third size L3_x in the first direction X is equal to the third size L3_y in the second direction Y, and the fourth size L4_x in the first direction X is equal to the fourth size L4_y in the second direction Y. Of course, in a specific implementation, the orthographic projections of the first opening, the light-emitting device, the first portion and the second portion on the base substrate may also be other shapes. That is, the second size L1_x in the first direction may be unequal to the second size L2_y in the second direction, the first size L1_x in the first direction may be unequal to the first size L1_y in the second direction, the third size L3_x in the first direction may be unequal to the third size L3_y in the second direction, and the fourth size L4_x in the first direction may be unequal to the fourth size L4_y in the second direction.

In some embodiments, in the first direction or in the second direction, the first size L1, the second size L2, and the third size L3 satisfy:

$$L 2 + 150 μm \geq L 1 \geq L 2 + 50 μm ;$$

$$L 3 \geq \sqrt{2} \cdot L 2 + 50 μm .$$

In the light-emitting substrate provided in the embodiments of the disclosure, L1≥L2+50 μm can avoid the first insulating protective layer interfering with the light emission of the light-emitting device due to the width of the first opening being too small. L2+150 μm≥L1 can avoid the first opening being too large, which in turn causes the size of the protective structure to be too large, affecting the light utilization rate of the light-emitting device and causing a large brightness loss.

It should be noted that when an outer contour of the orthographic projection of the first portion on the base substrate is a circle, L3 is a radius of the circle. Therefore, L3 is not less than half of the diagonal of the pattern of the orthographic projection of the light-emitting device on the base substrate. When the pattern of the orthographic projection of the light-emitting device on the base substrate is a square, L3≥√2·L2. On this basis, L3≥√2·L2+50 μm can ensure that the first portion at least completely covers the area between the first insulating protective layer and the light-emitting device, thereby avoiding the problem of bubbles still generated when the second portion is formed.

In some embodiments, 700 μm≥L2≥100 μm; the fourth size L4 satisfies: 1300 μm≥L4≥1000 μm.

In some embodiments, a distance between centers of two adjacent light-emitting devices in the first direction is L5_x. L5_x=a total length of the base substrate in the first direction/(a total number of light-emitting devices in a row in the first direction−1); the distance between the centers of two adjacent light-emitting devices in the second direction is L5_y, where L5_y=the total length of the base substrate in the second direction/(a total number of light-emitting devices in a column in the second direction−1).

In some embodiments, as shown in FIG. 3, a distance L5_x between centers A of two adjacent light-emitting devices 2 in the first direction X is equal to a distance L5_y between centers A of two adjacent light-emitting devices 2 in the second direction Y.

In some embodiments, in the first direction or in the second direction, the minimum distance between orthographic projections of two adjacent second portions on the base substrate is L6, L6=L5−2×L4; the distance L5 between the centers of two adjacent light-emitting devices needs to be greater than twice the fourth size L4, that is, L5_x>2×L4_x, and L5_y>2×L4_y, so that in the first direction or in the second direction, the minimum distance L6 between the orthographic projections of two adjacent second portions on the base substrate is greater than 0, thereby preventing adjacent protective structures from overlapping with each other.

It should be noted that in order to prevent adjacent protective structures from overlapping with each other, L6 needs to be greater than a safety distance between the protective structures. The safety distance is usually related to the position accuracy of the protective structure. If the position accuracy of the protective structure in the first direction or the second direction is +0.1 micron, the safety distance is 0.2 micron, that is, L6 needs to be greater than 0.2 μm.

In some embodiments, 10 mm≥L5_x≥3 mm, 10 mm≥L5_y≥3 mm. In this way, it is possible to avoid an increase in power consumption of the light-emitting substrate due to setting too many light-emitting devices while ensuring the brightness of the light-emitting substrate. When 10 mm≥L5≥3 mm and 1300 μm≥L4≥1000 μm, L6 is not less than 400 μm, that is, L6 is much larger than the safety distance, which can avoid mutual interference between the light emitted from two adjacent protective structures.

In some embodiments, the light-emitting device is a micro-sized inorganic light-emitting diode.

In a specific implementation, the micro-sized inorganic light-emitting diode is, for example, a mini light-emitting diode (Mini-LED) or a micro light-emitting diode (Micro-LED). The Mini-LED and Micro-LED are small in size and high in brightness, and can be widely used in display devices or backlight modules of the display devices. For example, a typical size (such as length) of Micro-LED is less than 100 μm, such as 10 μm to 80 μm; a typical size (such as length) of Mini-LED ranges from 80 μm to 350 μm, such as 80 μm to 120 μm. The light-emitting device can be at least one of Micro-LED or Mini-LED.

In some embodiments, as shown in FIG. 2, the first pad group 1021 includes a first sub-pad 1021-1 and a second sub-pad 1021-2. The light-emitting device 2 includes two pins (not shown), which are electrically connected to the first sub-pad 1021-1 and the second sub-pad 1021-2 of the first pad group 1021, respectively.

In a specific implementation, the light-emitting device further includes an anode, a light-emitting layer and a cathode, one of the two pins is electrically connected to the anode, and the other of the two pins is electrically connected to the cathode.

In some embodiments, the wiring layer further includes a plurality of second pad groups, a plurality of common voltage signal lines and a plurality of fixed voltage signal lines; the light-emitting substrate further includes a plurality of driver chips. The driver chip is bound to the second pad group. In a specific implementation, the second pad group includes: an address pad, a power supply pad, a ground pad and an output pad. The driver chip includes: a ground pin electrically connected to the ground pad, an output pin electrically connected to the output pad, an address pin electrically connected to the address pad, and a power supply pin electrically connected to the power supply pad. The address pad is electrically connected to the common voltage signal line. The plurality of light-emitting devices are divided into a plurality of light-emitting areas, each light-emitting area includes at least one light-emitting device, the at least one light-emitting device in each light-emitting area is electrically connected to the fixed voltage signal line through the first sub-pad included in the first pad group, and the at least one light-emitting device in each light-emitting area is electrically connected to the output pad through the second sub-pad included in the first pad group. For example, one second pad group corresponds to one light-emitting area, and a corresponding driver chip may control the operation of each light-emitting device in a light-emitting area corresponding to it. In a specific implementation, the power supply pad may provide a working voltage for the driver chip, and an output end of the driver chip outputs a driving signal through the output pad. The driving signal is a driving current, which is used to drive the light-emitting device in the light-emitting area electrically connected to the output pad. The driver chip provides a working voltage for the next-level driver chip through the power supply pad. The address pad includes, for example, a first address pad and a second address pad. The first address pad may receive an address signal for gating the driver chip of the corresponding address. The driver chip also generates a relay signal and outputs the relay signal through the second address pad. The relay signal serves as an address signal of a first address pad in the second pad group of the next level. The ground pad receives a common voltage signal transmitted by the common voltage signal line.

In some embodiments, a material of the first insulating protective layer includes white oil.

In some embodiments, materials of the first pad group, the second pad group, and each signal line in the wiring layer include copper.

In a specific implementation, the first pad group, the second pad group and each signal line in the wiring layer may include a single layer of copper or a double layer of copper. When the wiring layer includes a double layer of copper, the wiring layer further includes an insulating layer located between the double layers of copper, and the double layers of copper are electrically connected with each through a via penetrating the insulating layer.

In a specific implementation, the first pad group, the second pad group, and each signal line in the wiring layer may include a single layer of copper, and the single layer of copper included in the first pad group, the single layer of copper included in the second pad group, and the single layer of copper included in each signal line are arranged in the same layer. The first pad group, the second pad group, and each signal line in the wiring layer may include a double layer of copper, and each layer of copper included in the first pad group, the second pad group, and each signal line in the wiring layer is arranged in the same layer. This can facilitate the production of the wiring substrate.

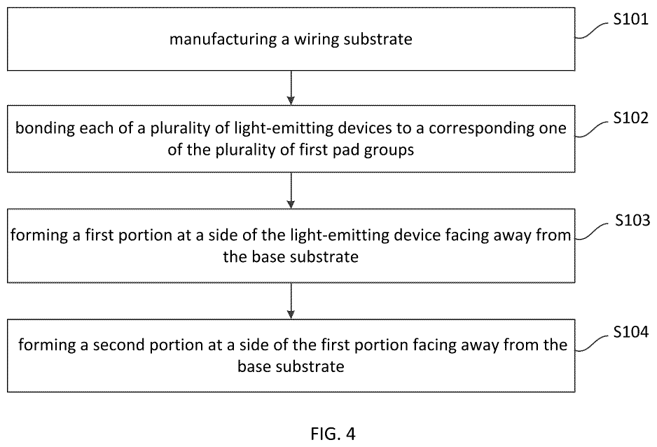

Based on the same inventive concept, the embodiments of the disclosure also provide a method for manufacturing a light-emitting substrate, as shown in FIG. 4, including following steps.

S101, manufacturing a wiring substrate. The wiring substrate includes: a base substrate, a wiring layer located at a side of the base substrate, and a first insulating protective layer located at a side of the wiring layer facing away from the base substrate; the wiring layer includes a plurality of first pad groups, the first insulating protective layer includes a plurality of first openings, and an orthographic projection of the first pad group on the base substrate is within an orthographic projection of the first opening on the base substrate.

S102, bonding each of a plurality of light-emitting devices to a corresponding one of the plurality of first pad groups.

S103, forming a first portion at a side of the light-emitting device facing away from the base substrate; an orthographic projection of the first portion on the base substrate at least covers an orthographic projection of an area between the light-emitting device and the first insulating protective layer on the base substrate.

S104, forming a second portion at a side of the first portion facing away from the base substrate; here, in a direction perpendicular to the base substrate, a maximum thickness of the first portion is smaller than a maximum thickness of the second portion.

The method for manufacturing the light-emitting substrate provided by the embodiments of the disclosure first forms a first portion that at least covers the area between the light-emitting device and the first insulating protective layer, and then forms a second portion, and the first portion and the second portion form a protective structure for protecting the light-emitting device. In this way, compared with forming the protective structure once, it is more conducive to exhausting the air between the first portion and the wiring substrate at the first opening, avoiding the existence of bubbles between the first portion and the wiring substrate, thereby avoiding abnormal brightness of the light emitted from the protective structure composed of the first portion and the second portion, improving the preparation yield of the light-emitting substrate, and improving the brightness uniformity of the light-emitting substrate.

In some embodiments, forming the first portion at the side of the light-emitting device facing away from the base substrate, includes:
printing a first adhesive material at a side of the light-emitting device facing away from the base substrate and curing the first adhesive material to form the first portion;
the forming the second portion at a side of the first portion facing away from the base substrate, includes:
printing a second adhesive material at the side of the first portion facing away from the base substrate and curing the second adhesive material to form a second portion.

The volume of the first portion is smaller than the volume of the second portion.

In the method for manufacturing the light-emitting substrate provided by the embodiments of the disclosure, the volume of the first portion is smaller than the volume of the second portion, that is, the volume of the first adhesive material printed is smaller than the volume of the second adhesive material printed, and the volume of the first adhesive material printed is smaller than half of the volume of the entire protective structure composed of the first portion and the second portion. The smaller volume of the first adhesive material printed is more conducive to discharging the air between the first portion and the wiring substrate at the first opening, avoiding the existence of bubbles between the first portion and the wiring substrate, thereby avoiding abnormal brightness of light emitted from the protective structure composed of the first portion and the second portion, improving the preparation yield of the light-emitting substrate, and improving the brightness uniformity of the light-emitting substrate.

In some embodiments, the first adhesive material and the second adhesive material include the same material.

Alternatively, in some embodiments, the first adhesive material and the second adhesive material include different materials.

In some embodiments, viscosity of the first adhesive material is less than viscosity of the second adhesive material.

In the method for manufacturing the light-emitting substrate provided by the embodiments of the disclosure, the first adhesive material printed first has a smaller viscosity, which is more conducive to air discharge, and can further avoid the existence of bubbles between the first portion and the wiring substrate, thereby avoiding abnormal brightness of light emitted from the protective structure composed of the first portion and the second portion, and is more conducive to improving the preparation yield of the light-emitting substrate and improving the brightness uniformity of the light-emitting substrate.

In a specific implementation, the related settings of the transmittance of the first adhesive material and the second adhesive material to visible light, the refractive index, the viscosity, and the size of the first portion, the size of the second portion, the size of the first opening and the size of the light-emitting device, etc. refer to the light-emitting substrate embodiment, which will not be repeated here.

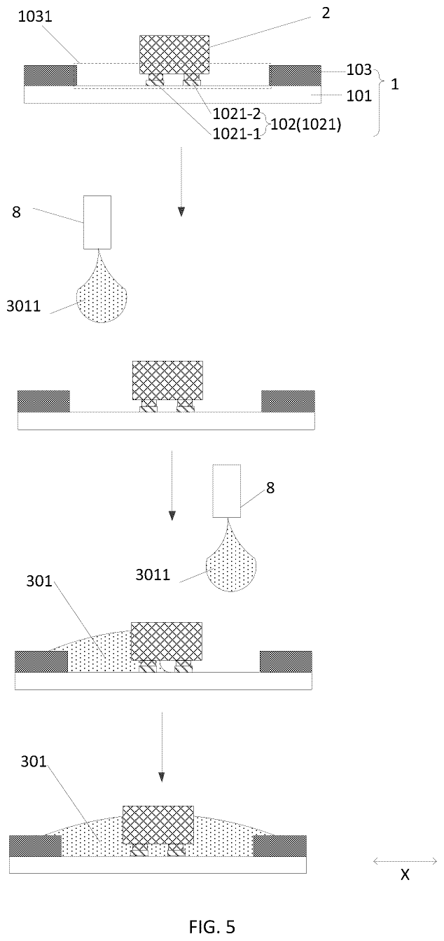

In some embodiments, as shown in FIG. 5, printing a first adhesive material at the side of the light-emitting device facing away from the base substrate, includes:
printing the first adhesive material 3011 at each side of the light-emitting device 2 to fill the area between the light-emitting device 2 and the first insulating protective layer 103 to form the first portion 301.

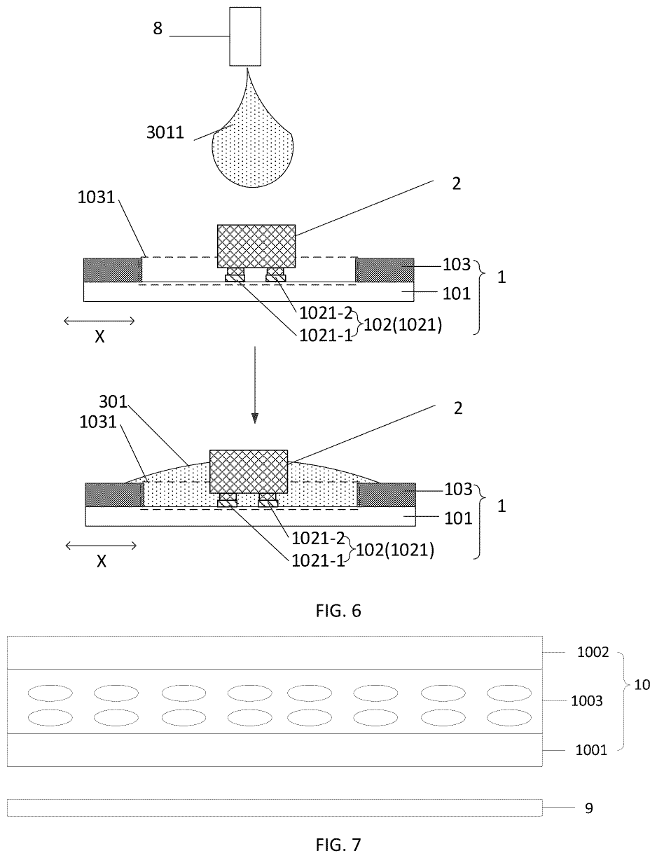

Alternatively, in some embodiments, as shown in FIG. 6, printing a first adhesive material at the side of the light-emitting device facing away from the base substrate, includes:
printing the first adhesive material 3011 above the side of the light-emitting device 2 facing away from the base substrate 1, so that the first adhesive material 3011 drips and at least covers the area between the light-emitting device 2 and the first insulating protective layer 103 to form a first portion.

It should be noted that the reference numeral 8 in FIG. 5 and FIG. 6 represents a nozzle of a printing device.

In some embodiments, manufacturing the wiring substrate specifically includes:
forming a conductive layer is formed on the base substrate and performing a patterning process on the conductive layer to form patterns of a plurality of first pad groups.

In a specific implementation, the wiring substrate further includes a second pad group and a plurality of signal lines; while performing the patterning process to form the patterns of the plurality of first pad groups, patterns of the second pad group and the plurality of signal lines can be formed.

In a specific implementation, the wiring substrate may include a single conductive layer, or the wiring substrate may include a double conductive layer. The material of the conductive layer includes copper, for example. If the wiring substrate includes a double conductive layer, the forming the conductive layer on the base substrate and performing the patterning process i on the conductive layer to form the patterns of the plurality of first pad groups and the second pad group and the plurality of signal lines, includes:
forming a first conductive layer on the base substrate, and performing the patterning process on the first conductive layer to form the first pad groups, the second pad group, and first conductive layer patterns of the plurality of signal lines;
forming a pattern of an insulating layer at a side of the first conductive layer facing away from the base substrate;
forming a second conductive layer at a side of the insulating layer facing away from the base substrate, and performing a patterning process on the second conductive layer to form the first pad groups, the second pad group and second conductive layer patterns of the plurality of signal lines.

In a specific implementation, the method for manufacturing the light-emitting substrate provided by the embodiments of the disclosure further includes:
preparing a plurality of light-emitting devices;
the bonding each of the plurality of light-emitting devices to a corresponding one of the plurality of first pad groups, includes:
transferring the plurality of light-emitting devices to the wiring substrate, so that the light-emitting devices are bound to the first pad groups in a one-to-one correspondence.

The embodiments of the disclosure provide a display device, as shown in FIG. 7, includes the light-emitting substrate 9 provided in the embodiments of the disclosure.

In some embodiments, as shown in FIG. 7, the display device further includes: a display panel 10 located at a light-emitting side of the light-emitting substrate 9.

That is, in a specific implementation, the light-emitting substrate provided by the embodiments of the disclosure is used as the backlight source of the display panel.

In a specific implementation, the display panel is a liquid crystal display panel. As shown in FIG. 7, the display panel 10 includes: an array substrate 1001 and an opposite substrate 1002 arranged opposite to each other, and a liquid crystal layer 1003 located between the array substrate 1001 and the opposite substrate 1002.

In a specific implementation, the array substrate includes a plurality of sub-pixel units, the sub-pixel units include thin film transistors and pixel electrodes electrically connected to the thin film transistors. The opposite substrate includes a black matrix and a plurality of color resists, the black matrix includes a plurality of opening areas corresponding to the sub-pixel units, and the color resists are at least located in the opening areas. The array substrate or the opposite substrate further includes a common electrode. The color resists include, for example, a red resist(s), a blue resist(s), and a green resist(s).

The display device provided in the embodiments of the disclosure is any product or component with a display function, such as a mobile phone, a tablet computer, a television, a display, a laptop computer, a digital photo frame, a navigator, etc. Other essential components of the display device should be understood by a person skilled in the art, and will not be described in detail here, nor should they be used as a limitation of the disclosure. The implementation of the display device can refer to the embodiments of the light-emitting substrate described above, and the repeated parts will not be described in detail.

In summary, in the light-emitting substrate and a manufacturing method therefor, and the display device provided by the embodiments of the disclosure, the protective structure includes a first portion and a second portion, and the second portion is located at the side of the first portion facing away from the base substrate, that is, in the embodiments of the disclosure, the protective structure is fabricated in two steps: first forming the first portion that at least covers the area between the light-emitting device and the first insulating protective layer, and then forming the second portion. In this way, compared with forming the protective structure once, it is more conducive to exhausting the air between the protective structure and the wiring substrate at the first opening, avoiding the existence of bubbles between the protective structure and the wiring substrate, thereby avoiding abnormal brightness of the light emitted from the protective structure, improving the yield of the light-emitting substrate, and improving the brightness uniformity of the light-emitting substrate.

Although the preferred embodiments of the disclosure have been described, those skilled in the art can make various changes and modifications to the embodiments once the basic inventive concept is appreciated. Therefore, the appended claims are intended to be interpreted as including the preferred embodiments and all changes and modifications falling within the scope of the disclosure.

Apparently, those skilled in the art can make various changes and modifications to the embodiments of the disclosure without departing from the spirit and scope of the embodiments of the disclosure. In this way, if the modifications and variations of the embodiments of the disclosure fall within the scope of the claims of the disclosure and their equivalent technologies, the disclosure also intends to include these modifications and variations.

1. A light-emitting substrate, wherein the light-emitting substrate comprises:
a wiring substrate, comprising:
a base substrate,
a wiring layer, located at a side of the base substrate, and
a first insulating protective layer, located at a side of the wiring layer facing away from the base substrate;
wherein the wiring layer comprises a plurality of first pad groups, the first insulating protective layer comprises a plurality of first openings, and an orthographic projection of the first pad group on the base substrate is within an orthographic projection of the first opening on the base substrate;
a plurality of light-emitting devices, located at a side of the plurality of first pad groups facing away from the base substrate; wherein each of the plurality of light-emitting devices is bound to a corresponding one of the plurality of first pad groups; and
a plurality of protective structures, located at a side of the plurality of light-emitting devices facing away from the base substrate; wherein each of the plurality of protective structures comprises: a first portion, and a second portion located at a side of the first portion facing away from the base substrate; and an orthographic projection of the first portion on the base substrate at least covers an orthographic projection of a gap between the light-emitting device and the first insulating protective layer on the base substrate.

2. The light-emitting substrate according to claim 1, wherein
the first portion is provided with a first transmittance for visible light,
the second portion is provided with a second transmittance for the visible light,
an absolute value of a difference between the first transmittance and the second transmittance is less than or equal to 5%, and
the first transmittance is greater than or equal to 90%, and the second transmittance is greater than or equal to 90%.

3. The light-emitting substrate according to claim 1, wherein the first portion is provided with a first refractive index for visible light, the second portion is provided with a second refractive index for the visible light, and an absolute value of a difference between the first refractive index and the second refractive index is less than or equal to 0.2.

4. The light-emitting substrate according to claim 1, wherein
a material of the first portion comprises a first adhesive material, and a material of the second portion comprises a second adhesive material; and
viscosity of the first adhesive material is less than viscosity of the second adhesive material.

5. The light-emitting substrate according to claim 4, wherein the viscosity of the first adhesive material is greater than or equal to 3000 Pa·s and less than 6000 Pa·s; and
the viscosity of the second adhesive material is greater than or equal to 6000 Pas and less than or equal to 9000 Pa·s.

6. The light-emitting substrate according to claim 1, wherein a volume of the first portion is smaller than a volume of the second portion.

7. The light-emitting substrate according to claim 6, wherein a maximum distance h1 from a surface of the light-emitting device facing away from the base substrate to the base substrate, a maximum distance h2 from a surface of the first portion facing away from the base substrate to the base substrate, and a maximum distance h3 from a surface of the second portion facing away from the base substrate to the base substrate satisfy:
$$0.53 \text{≦≧} h 2 / h 1 \text{≦≧} 1.33 , 3 \text{.33} \text{≦≧} h 3 / h 1 \text{≦≧} 5 .$$

8. The light-emitting substrate according to claim 7, wherein the maximum distance h2 from the surface of the first portion facing away from the base substrate to the base substrate is greater than a maximum distance h4 from a surface of the first insulating protective layer facing away from the base substrate to the base substrate.

9. The light-emitting substrate according to claim 8, wherein 0.13≤h4/h1≤0.4.

10. The light-emitting substrate according to claim 9, wherein 100 μm≤h1≤200 μm, 20 μm≤h4≤60 μm, 80 μm≤=h2≤200 μm, and 500 μm≤h3≤750 μm.

11. The light-emitting substrate according to claim 1, wherein the orthographic projection of the first portion on the base substrate is within an orthographic projection of the second portion on the base substrate.

12. The light-emitting substrate according to claim 11, wherein the plurality of light-emitting devices are arranged in an array along a first direction and a second direction, and the first direction intersects the second direction;
in the first direction or in the second direction, the orthographic projection of the first opening on the base substrate is provided with a first size L1, an orthographic projection of the light-emitting device on the base substrate is provided with a second size L2, the orthographic projection of the first portion on the base substrate is provided with a third size L3, and the orthographic projection of the second portion on the base substrate is provided with a fourth size L4, and the first size L1, the second size L2, the third size L3 and the fourth size L4 satisfy following relationship: L1> L2, L3>L1, L4>L3.

13. The light-emitting substrate according to claim 12, wherein in the first direction or in the second direction, the first size L1, the second size L2, and the third size L3 satisfy:
$$L 2 + 150 μm \geq L 1 \geq L 2 + 50 μm ;$$
$$L 3 \geq \sqrt{2} \cdot L 2 + 50 μm .$$

14. The light-emitting substrate according to claim 13, wherein 700 μm≥L2≥100 μm; and the fourth size L4 satisfies: 1300 μm≥L4≥1000 μm.

15. The light-emitting substrate according to claim 1, wherein a surface of the side of the first portion facing away from the base substrate and a surface of a side of the second portion facing away from the base substrate are curved surfaces.

16. A method for manufacturing a light-emitting substrate, wherein the method comprises:
manufacturing a wiring substrate; wherein the wiring substrate comprises: a base substrate, a wiring layer located at a side of the base substrate, and a first insulating protective layer located at a side of the wiring layer facing away from the base substrate; the wiring layer comprises a plurality of first pad groups, the first insulating protective layer comprises a plurality of first openings, and an orthographic projection of the first pad group on the base substrate is within an orthographic projection of the first opening on the base substrate;
bonding each of a plurality of light-emitting devices to a corresponding one of the plurality of first pad groups;
forming a first portion at a side of the light-emitting device facing away from the base substrate; wherein an orthographic projection of the first portion on the base substrate at least covers an orthographic projection of a gap between the light-emitting device and the first insulating protective layer on the base substrate;
forming a second portion at a side of the first portion facing away from the base substrate; wherein in a direction perpendicular to the base substrate, a maximum thickness of the first portion is smaller than a maximum thickness of the second portion.

17. The method according to claim 16, wherein:
the forming the first portion at the side of the light-emitting device facing away from the base substrate comprises:
printing a first adhesive material at the side of the light-emitting device facing away from the base substrate and curing the first adhesive material to form the first portion;
the forming the second portion at the side of the first portion facing away from the base substrate comprises:
printing a second adhesive material at the side of the first portion facing away from the base substrate and curing the second adhesive material to form the second portion;
wherein a volume of the first portion is smaller than a volume of the second portion.

18. A display device, wherein the display device comprises the light-emitting substrate according to claim 1.
